(19) United States
(12) Patent Application Publication
(10) Pub. No.: US 2015/0171181 A1
(43) Pub. Date: Jun. 18, 2015

(54) ONO STRUCTURE WITH SEPARATED ELECTRON TRAPPING

(71) Applicant: MACRONIX INTERNATIONAL CO., LTD., Hsinchu (TW)

(72) Inventor: Chi-Pin LU, Hsinchu City (TW)

(73) Assignee: MACRONIX INTERNATIONAL CO., LTD., Hsinchu (TW)

(21) Appl. No.: 14/109,794

(22) Filed: Dec. 17, 2013

(51) Int. Cl. H01L 29/51; H01L 21/28; H01L 29/66; H01L 29/792

(52) U.S. Cl. CPC H01L 29/511; H01L 29/792; H01L 21/28273; H01L 29/66833

(57) ABSTRACT

A method of forming a charge-trapping structure in a memory device is disclosed. The method comprises the steps of forming a gate oxide and gate electrode on a semiconductor substrate, performing undercut etching on the gate oxide layer, annealing in a nitrogen containing environment, further creating funnel-like openings on both sides of the gate oxide layer, and conformally forming the charge-trapping structure on the substrate surface.

### BACKGROUND

The present application relates generally to a non-volatile memory semiconductor device and a method for manufacturing said device; more particularly, the present application relates to an oxide-nitride-oxide (ONO) structure in the non-volatile memory semiconductor device and a method for manufacturing said structure.

Non-volatile memory refers to a semiconductor memory that is able to continually store information even when a supply of electricity is removed from the device. Typically, non-volatile memory can be programmed with data, read and/or erased, and the programmed data can be stored for a long period of time prior to being erased, even as long as ten years.

A certain type of non-volatile memory device is one that is programmed by inducing hot electrons to be injected from a substrate to an ONO dielectric. The ONO dielectric is generally comprised of a silicon nitride layer sandwiched between a bottom oxide layer and a top oxide layer. The silicon nitride layer provides a charge-trapping mechanism for programming the memory cell.

One of the conventional methods of forming an ONO structure in a non-volatile memory is described below.

First, as shown in FIG. 1a, a gate oxide 12 and a gate layer 14 are formed on a silicon substrate 10. Then, as shown in FIG. 1b, the gate oxide is subjected to undercut etching to create an undercut profile in the gate oxide layer 12a. Then, as shown in FIG. 1c, a re-oxidation is performed to form an additional oxide layer 16 again on the entire substrate surface. As can be seen from the figure, the reoxidation process increases the gate oxide thickness and also creates an encroachment profile 12b on the gate oxide layer 12a.

Then, as shown in FIG. 1d, the re-oxidized dielectric 16 is removed from the surface. Then, as shown in FIG. 1e, a tunnel/top dielectric layer 18 is formed on the feature surface. Thereafter, as shown in FIG. 1f, a trap SiN layer 20 is formed and re-oxidized to form a second oxide layer 22, thereby completing the ONO structure. Due to the poor profile of the first oxide layer 18 in the ONO structure, the subsequently formed nitride trapping SiN layer 20 will have poor fill capability and may even have seams or voids 26 inside. Those problems will degrade the performance and/or reliability of the memory devices.

### BRIEF SUMMARY

Disclosed embodiments provide a method of forming a charge-trapping structure in a memory device. Disclosed methods comprise forming a gate oxide and gate electrode on a semiconductor substrate, performing undercut etching on the gate oxide layer, annealing the structure in a nitrogen-containing environment, further creating funnel-like openings on both sides of the gate oxide layer, and conformally forming the charge-trapping structure on the substrate surface.

In an embodiment, the nitrogen-containing environment comprises NO, and the annealing is performed in the temperature range of approximately 850° C. to 950° C., and preferable near 900° C., and the annealing time is between 30 minutes and 60 minutes.

In an embodiment, the charge-trapping structure is a oxide/nitride/oxide (ONO) structure, and each layer in the ONO structure is between about 10 Å and about 30 Å in thickness.

In an embodiment, the opening angle of the funnel-like opening is larger than 45 degrees.

Another objective of the present invention is to provide a memory device. The memory device comprises a gate oxide layer and a gate electrode on a semiconductor substrate, and the charge-trapping structure is conformally formed on the substrate surface to fill in the funnel-like openings. The gate oxide layer is undercut and similarly has funnel-like openings on both sides.

In an embodiment, the gate oxide layer comprises nitrogen at the interface with a nitrogen concentration of 5% to 7%.

Another objective of the present invention is to provide a memory device. The memory device comprises an oxide layer on a substrate, and a conductive layer disposed on the oxide layer. The oxide layer comprising a bird's beak shape recess, a charge trapping layer disposed in the bird's beak shape recess, and the oxide has higher nitrogen concentration in the interface between the substrate and the oxide layer than that in the middle of the oxide layer.

### BRIEF DESCRIPTION OF THE DRAWINGS

FIGS. 1a-1f illustrate a cross-sectional view of a conventional method of forming the ONO dielectric of the non-volatile memory device.

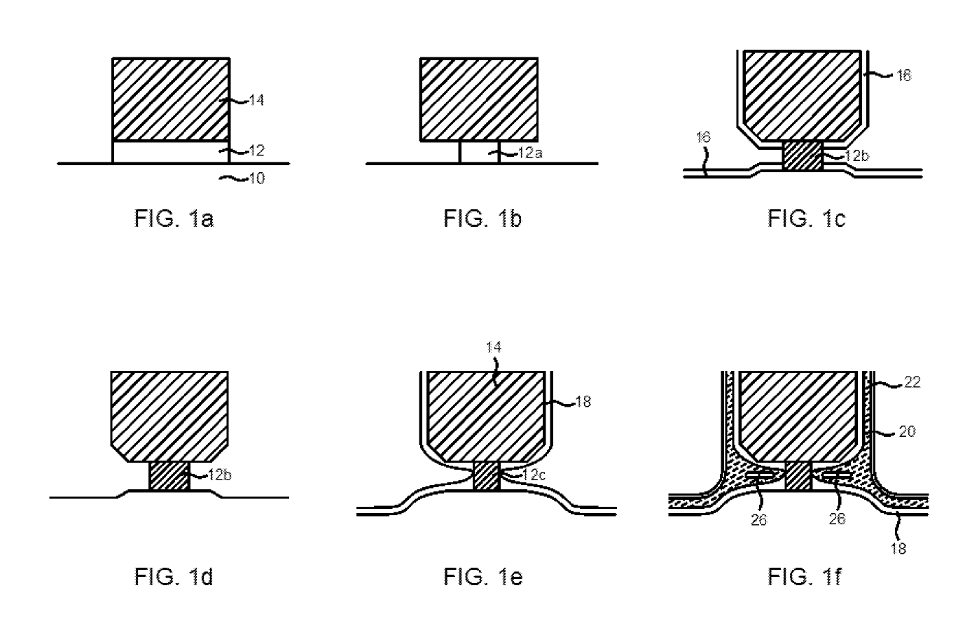

FIGS. 2a-2f illustrate a cross-sectional view of a method of forming the ONO dielectric of the non-volatile memory device according to one embodiment of the present invention.

### DETAILED DESCRIPTION

The invention will now be described in further detail by reference to the drawings, which illustrate one embodiment of the invention. The drawings are diagrammatic, showing features of the invention and their relationship to other features and structures. The drawings are not made to scale.

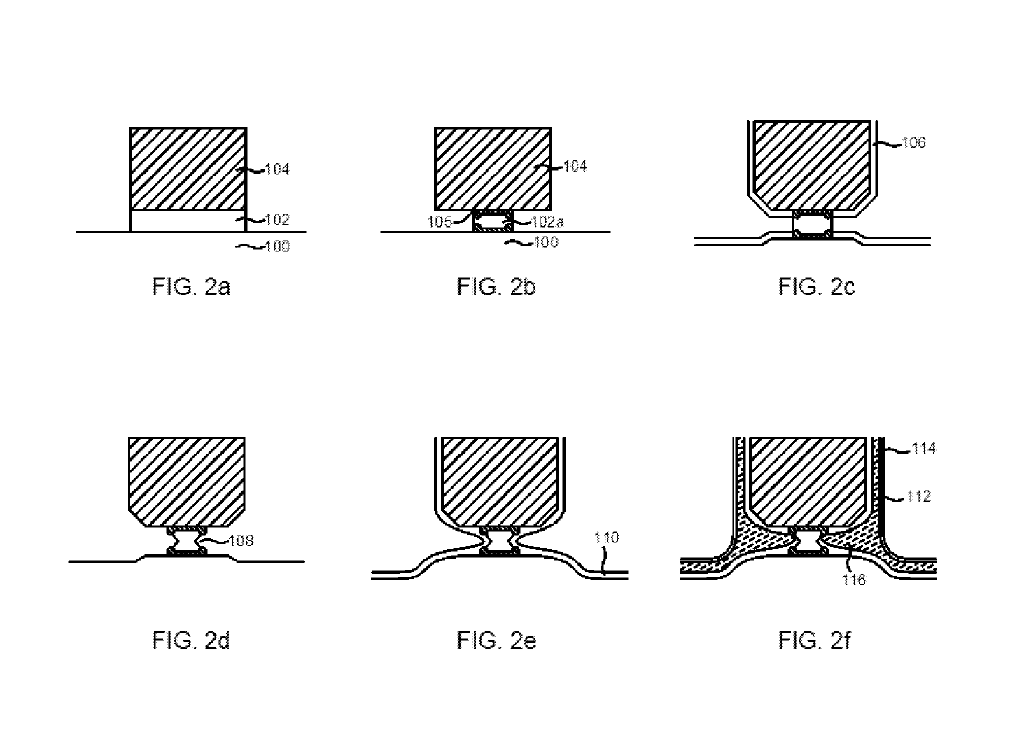

According to one embodiment, the non-volatile memory can be fabricated using the process flow described below. The resulting structures at various stages in the process flow are shown through the diagrammatic cross sectional views of FIGS. 2a-2f.

FIG. 2a is a cross-sectional diagram illustrating a cross-sectional view of an exemplary partially completed memory cell. A gate oxide layer 102 and a gate electrode layer 104 are formed on a silicon substrate 100. Thereafter, the gate oxide layer 102 and the gate electrode layer 104 are patterned using the conventional photolithographic process.

FIG. 2b is a cross-sectional diagram illustrating a cross-sectional view of an exemplary partially completed memory cell. Undercut etching has been performed to undercut the gate oxide layer 102a below the gate electrode 104, followed by a nitrogen anneal as shown in FIG. 2b. The undercut etching of the gate oxide layer can use either wet or dry anisotropic etching to create the undercut profile. One of the important features of the present disclosure is a subsequent nitrogen annealing step to strengthen the SiO₂/Si interface and suppress the encroachment issue in the gate oxide layer.

In one embodiment, the nitrogen annealing step involves using NO gas in the temperature range of approximately 850° C. to 950° C., and preferably near 900° C. The annealing time may be set between 30 minutes and 60 minutes. Thereafter, it can be found by the SIMS analysis that the nitrogen will diffuse into SiO₂ and pile up at the SiO₂/Si interface with a nitrogen concentration of 5% to 7%. However, in another embodiment, N₂O gas is used in the nitrogen annealing step.

FIG. 2c is a cross-sectional diagram illustrating a cross-sectional view of an exemplary partially completed device. A re-oxidation step is performed to form an oxide layer 106 again on the entire substrate surface. In one embodiment, the re-oxidation is performed by RTO (rapid thermal oxidation) in the temperature range of approximately _{—}800_° C. to _{—}900_° C. for about _{—}30 seconds to grow an oxide layer having a thickness of about 30 Å.

FIG. 2d is a cross-sectional diagram illustrating a cross sectional view of an exemplary partially completed device after the reoxidized dielectric 106 is removed from the surface. The nitrogen diffuses into SiO₂ and accumulates at the SiO₂/Si interface 105 which can act as an etch stop, and therefore a funnel-like opening 108 is formed to further undercut the remaining gate oxide in the middle portion. In one embodiment, the dielectric removal step involves using a dilute HF cleaning solution prior to a second undercut etching. Other etching technology can also be used. In one embodiment, the opening angle of the funnel-like opening 108 is larger than about 45 degrees, and the depth of the funnel is about ⅓ of the cell size.

FIG. 2e is a cross-sectional diagram illustrating a cross-sectional view of an exemplary partially completed device. A tunnel/top dielectric layer 110 starts forming on the surface again. In one embodiment, the tunnel/top dielectric layer 110 is formed by wet oxidation.

FIG. 2f is a cross-sectional diagram illustrating a cross-sectional view of an exemplary partially completed device. The trapping dielectric layer 112 and a second oxide layer 114 are formed in the entire substrate surface. In one embodiment, the trapping dielectric layer 112 is a nitride layer to form an oxide 110/nitride 112/oxide 114 (ONO) structure. Each of the first and second oxide layers 110, 114 and the dielectric nitride layer 112 is preferably between about 10 Å and 30 Å in thickness. For example, the thickness of the first oxide layer 110 may be about 18 Å, the thickness of the nitride layer 112 may be about 20 Å, and the thickness of the second oxide layer 114 may be about 15 Å,

Since the funnel-like undercut structure will provide a better environment for filling in the nitride layer 116, the deep undercut structure will improve the characteristics of the memory cell. For instance, program disturb and second bit effect, which causing by neighbor program bits, are reduced. Because the isolation performance between each bits is getting better while deeper undercut is performed.

It will be appreciated that this arrangement is exemplary in nature and other arrangements may also be used. For example, the thickness of the oxide layer and/or nitride layer in the ONO structure as well as the cell size can be changed based on the manufacturing nodes.

While various embodiments in accordance with the disclosed principles have been described above, it should be understood that they have been presented by way of example only, and are not limiting. For example, the memory device can be generally constructed as oxide layer having a bird's beak shape recess, a charge trapping layer disposed in the bird's beak shape recess, and the oxide has higher nitrogen concentration in the interface between the substrate and the oxide layer than that in the middle of the oxide layer. Thus, the breadth and scope of the invention(s) should not be limited by any of the above-described exemplary embodiments, but should be defined only in accordance with the claims and their equivalents issuing from this disclosure. Furthermore, the above advantages and features are provided in described embodiments, but shall not limit the application of such issued claims to processes and structures accomplishing any or all of the above advantages.

Additionally, the section headings herein are provided for consistency with the suggestions under 37 C.F.R. 1.77 or otherwise to provide organizational cues. These headings shall not limit or characterize the invention(s) set out in any claims that may issue from this disclosure. Specifically, and by way of example, a description of a technology in the “Background” is not to be construed as an admission that technology is prior art to any invention(s) in this disclosure. Neither is the “Summary” to be considered as a characterization of the invention(s) set forth in issued claims. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings set forth herein.

What is claimed is:

1. A method of forming a charge-trapping structure in a memory device, comprising:
forming a gate oxide and gate electrode on a semiconductor substrate;
performing undercut etching on the gate oxide layer;
performing an anneal in a nitrogen-containing environment;
creating funnel-like openings on both sides of the gate oxide layer; and
conformally forming the charge-trapping structure on the substrate surface.

2. The method of claim 1, wherein the nitrogen-containing environment comprises NO or N₂O.

3. The method of claim 2, wherein the annealing is performed at an annealing temperature in a temperature range of about 850° C. to about 950° C.

4. The method of claim 2, wherein the annealing is performed at an annealing temperature of about 900° C.

5. The method of claim 2, wherein the annealing is performed during an annealing time period between about 30 minutes and about 60 minutes.

6. The method of claim 3, wherein the annealing is performed during an annealing time period between about 30 minutes and about 60 minutes.

7. The method of claim 4, wherein the annealing is performed during an annealing time period between about 30 minutes and about 60 minutes.

8. The method of claim 1 wherein the charge-trapping structure is a oxide/nitride/oxide (ONO) structure.

9. The method of claim 8, wherein each layer in the ONO structure is between about 10 Å and 30 Å in thickness.

10. The method of claim 1, wherein the opening angle of the funnel-like openings are larger than about 45 degrees.

11. A memory device, comprising:
a gate oxide layer and a gate electrode on a semiconductor substrate, wherein the gate oxide layer is undercut and has funnel-like openings on both sides; and
a charge-trapping structure on the substrate surface conformally formed to fill in the funnel-like openings.

12. The memory device of claim 11, wherein the gate oxide layer comprises nitrogen at the interface.

13. The memory device of claim 12, wherein the gate oxide layer comprises nitrogen at the interface with a nitrogen concentration of 5˜7%.

14. The memory device of claim 11 wherein the charge-trapping structure is oxide/nitride/oxide (ONO) structure.

15. The memory device of claim 14, wherein each layer in the ONO structure is between about 10˜30 Å in thickness.

16. The memory device of claim 11, wherein the opening angle of the funnel-like opening is larger than 45 degree.

17. A memory device, comprising:
an oxide layer on a substrate;
a conductive layer disposed on the oxide layer, wherein the oxide layer comprising a bird's beak shape recess,
a charge trapping layer disposed in the bird's beak shape recess, and the oxide has higher nitrogen concentration in the interface between the substrate and the oxide layer than that in the middle of the oxide layer.

18. The memory device of claim 17, wherein the gate oxide layer comprises nitrogen at the interface.

19. The memory device of claim 18, wherein the gate oxide layer comprises nitrogen at the interface with a nitrogen concentration of 5˜7%.
